(19) United States
(12) Patent Application Publication
(10) Pub. No.: US 2009/0213540 A1
(43) Pub. Date: Aug. 27, 2009

(54) FIXING APPARATUS FOR FUNCTIONAL MODULE

(75) Inventors: Bing-Jun Zhang, Shenzhen City (CN); Lian-Zhong Gong, Shenzhen City (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/261,015

(22) Filed: Oct. 29, 2008

(30) Foreign Application Priority Data
Feb. 21, 2008 (CN) 200810300369.9

(51) Int. Cl. G06F 1/16; H05K 5/02

(52) U.S. Cl. 361/679.58

(57) ABSTRACT

A fixing apparatus for a functional module having a front wall and a first sidewall has a chassis with a sideboard having fastening holes, a first locking member sliding on the first sidewall and including a number of claws, and a driving fork sliding on the front wall of the functional module and having at least one wedge slidably engaging the first locking member. When the driving fork slides relative to the front wall of the functional module, the first locking member withdraws the claws from the fastening holes of the chassis or to extend the claws into the fastening holes.

### BACKGROUND

1. Field of the Invention

The disclosure relates to hardware fixing and, particularly, to a fixing apparatus readily allowing secure installation or removal of a functional module to or from a chassis.

2. Description of Related Art

A server system includes a chassis and several functional modules mounted therein. The chassis includes a pair of apertures defined in two opposite sidewalls thereof. Each functional module includes a pair of fasteners corresponding to the aperture board of the chassis, and a pair of operating members respectively attached to the fasteners. During attachment or detachment of the functional module to or from the chassis, the pair of fasteners must be operated at the same time, an inconvenient arrangement.

### BRIEF DESCRIPTION OF THE DRAWINGS

FIG. 1 is an exploded, isometric view of an exemplary embodiment of a fixing apparatus for functional modules.

FIG. 2 is similar to FIG. 1, but viewed from another aspect in the absence of a chassis of FIG. 1.

FIG. 3 is an assembled view of FIG. 2, showing the fixing apparatus in a locked position.

FIG. 4 is another assembled view of FIG. 2, showing the fixing apparatus in a released position.

### DETAILED DESCRIPTION

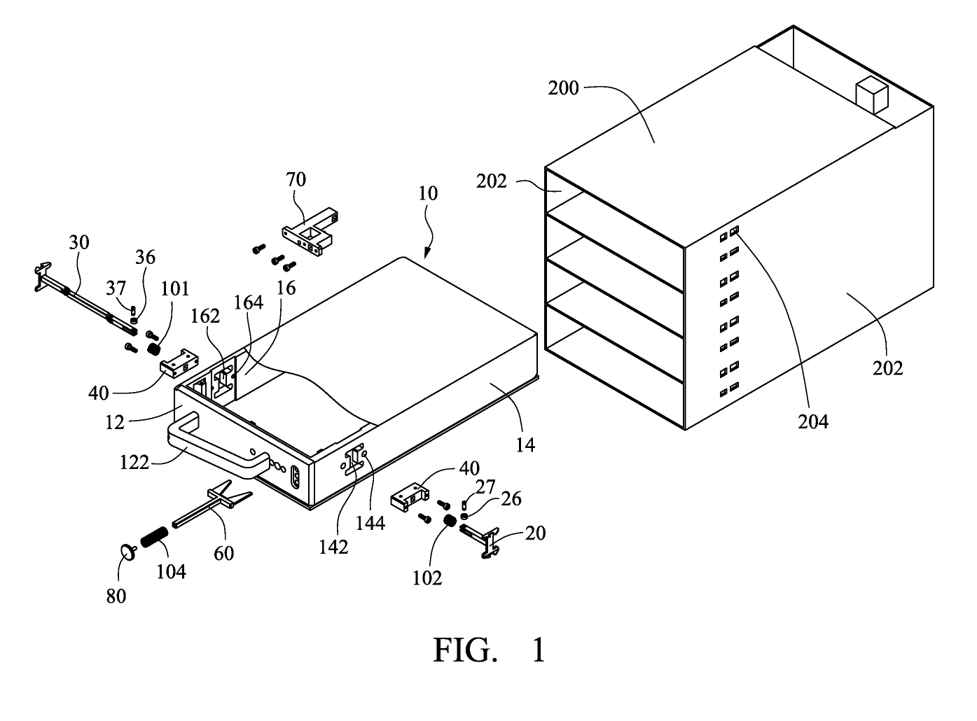

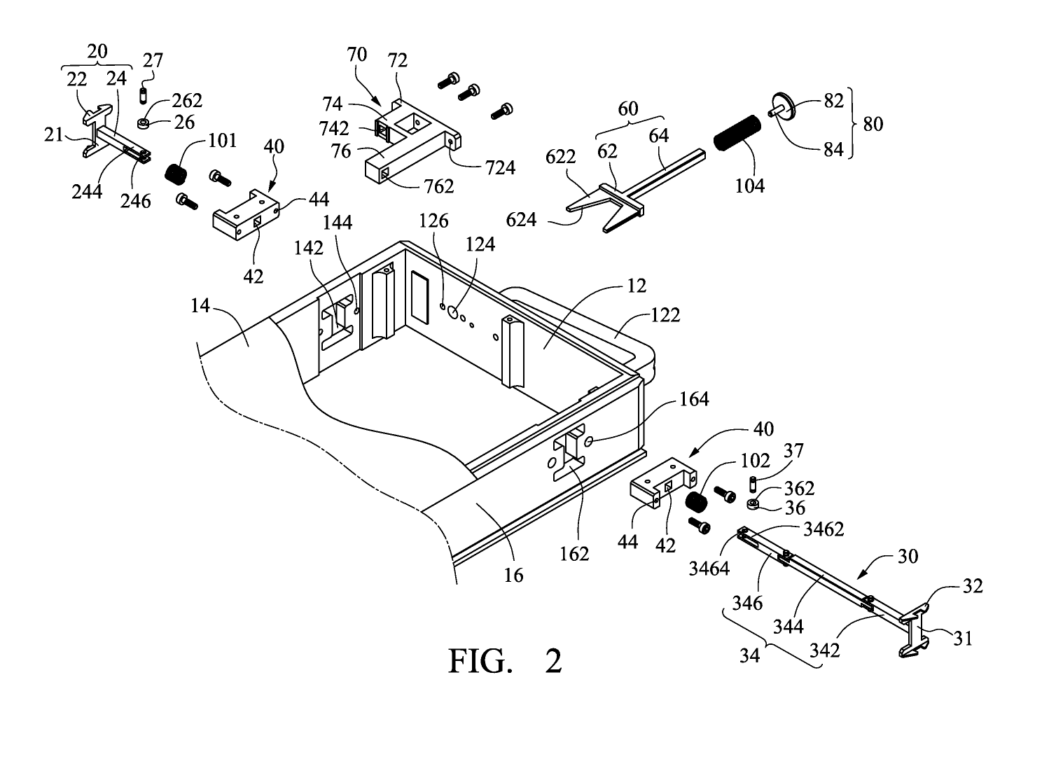

Referring to FIGS. 1 and 2, an embodiment of a fixing apparatus for a functional module 10 on a chassis 200 of a server includes a first locking member 20, a second locking member 30, a pair of first guiding blocks 40, a driving fork 60, a second guiding block 70, a button member 80, and a plurality of resilient members. The resilient members are coiled springs 101, 102, and 104.

The functional module 10 includes a front wall 12, a first sidewall 14, and a second sidewall 16. The front wall 12 includes a handle 122 formed on the outside thereof, a through hole 124 defined therein beside one end of the handle 122, and a plurality of fixing holes 126 defined therein beside the through hole 124. The first sidewall 14 includes an I-shaped opening 142 defined therein, and a pair of fixing holes 144 defined therein beside the opening 142. The second sidewall 16 includes an I-shaped opening 162 defined therein, and a pair of fixing holes 164 defined therein beside the opening 162. The opening 162 and the fixing holes 164 respectively correspond to the opening 142 and fixing holes 144 of the first sidewall 14.

The chassis 200 includes a pair of sideboards 202 each having a plurality of pairs of fastening holes 204 defined therein.

The first locking member 20 includes an I-shaped flat panel 21, and a driving arm 24 perpendicularly extending from one side of the flat panel 21. Two pairs of claws 22 respectively extend from an upper and a lower edge of the other side of the flat panel 21, extending opposite to the driving arm 24. The driving arm 24 includes a pair of spaced and parallel walls at a distal end portion thereof, and a U-shaped receiving space 244 defined between the walls receives a roller 26 with a through hole 262. A pair of pivot holes 246 is defined in the distal end of the walls, receiving a shaft 27 extending therethrough.

The second locking member 30 includes an I-shaped flat plane 31, and a driving arm 34 perpendicularly extending from one side of the flat panel 31. The driving arm 34 includes a first driving rod 342, a second driving rod 344 attachable to a distal end of the first driving rod 342, and a third driving rod 346 attachable to a distal end of the second driving rod 344. Two pairs of claws 32 respectively extend from an upper and a lower edge of the flat panel 31, extending opposite to the driving arm 34. The third driving rod 346 includes a pair of spaced and parallel walls at a distal end portion thereof, and a U-shaped receiving space 3462 defined between the walls receiving a roller 36 with a through hole 362. A pair of pivot holes 3464 is defined in the distal end of the walls for a shaft 37 extending therethrough.

Each of the first guiding blocks 40 is U-shaped and includes a passage 42 defined in a bottom portion thereof, and two threaded hole 44 defined in two side portions thereof.

The driving fork 60 includes a bar 64 with a fork 62 formed at one end thereof. The fork 62 includes a pair of symmetrical wedges 622. Each wedge 622 includes an angled edge 624 formed at the inside thereof, allowing the rollers 26, 36 to slide therealong. A threaded hole is defined in a distal end portion of the bar 64.

The second guiding block 70 includes a baseboard 72, a first post 74 and a second post 76 perpendicularly extending from the baseboard 72. The first post 74 is shorter than and connected to the post 76 at a distal end thereof via a rib. A plurality of threaded holes 724 is defined in the baseboard 72, corresponding to the fixing holes 126 of the front wall 12 of the functional module 10. A passage 742 perpendicular to the baseboard 72 is defined in the post 74. A passage 762 parallel to the baseboard 762 is defined in a distal end portion of the post 76.

The button member 80 includes a round operating portion 82 and a threaded rod 84 perpendicularly extending from the operating portion 82, corresponding to the threaded hole of the bar 64 of the driving fork 60.

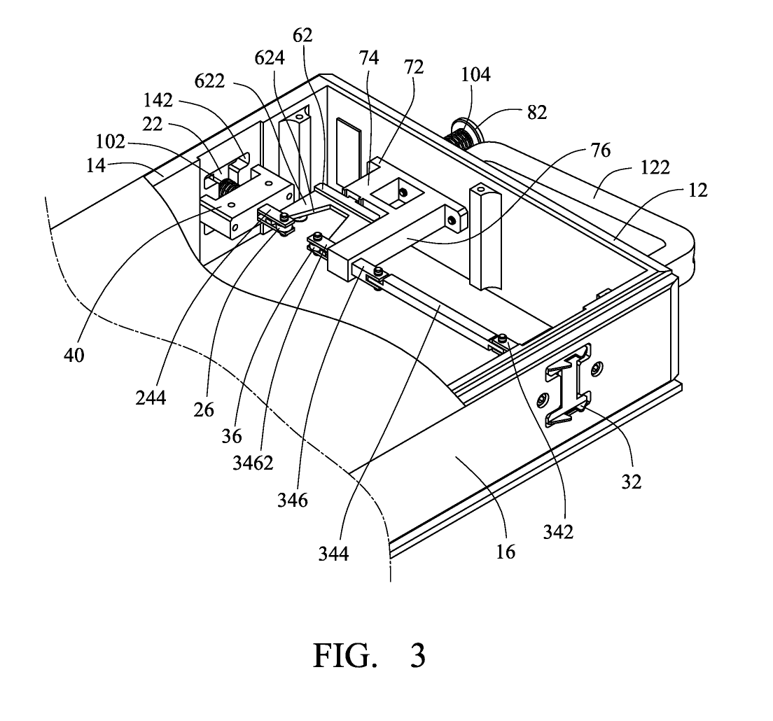

Referring also to FIG. 3, in assembly, one of the first guiding blocks 40 is attached to an inner side of the first sidewall 14 of the functional module 10, with the passage 42 aligning with the opening 142 and a pair of fasteners extending through the fixing holes 144 of the functional module 10 to engage the threaded hole 44 of the corresponding first guiding block 40. The coiled spring 101 is disposed between the first guiding block 40 and the flat panel 21 of the first locking member 20. The driving arm 24 of the first lock member 20 extends through the opening 142, the coiled spring 101 and the passage 42 of the first guiding block 40. The roller 26 is received in the receiving space 244 of the first locking member 20 and the shaft 27 pivotally extends through the pivot holes 246 of the first locking member 20 and the through hole 262 of the roller 26. The flat panel 21 is slidably received in the opening 142 of the first sidewall 14.

The other first guide blocks 40 is attached to an inner side of the second sidewall 16 of the functional module 10, with the passage 42 aligning with the opening 162 and a pair of fasteners extending through the fixing holes 164 of the functional module 10 to engage the threaded hole 44 of the first guiding block 40. The coiled spring 102 is disposed between the first guiding block 40 and the flat panel 32 of the second locking member 30. The first driving rod 342 of the driving arm 34 of the second lock member 30 extends through the opening 162, the coiled spring 102, and the passage 42 of the first guiding block 40. The roller 36 is received in the receiving space 3462 of the second locking member 30 and the shaft 37 pivotably extends through the pivot holes 3464 of the second locking member 30 and the through hole 362 of the roller 36. The flat panel 31 is slidably received in the opening 162 of the second sidewall 16.

The second guiding block 70 is attached to an inner side of the front wall 12 of the functional module 10, with the passage 742 aligning with the through hole 124 and a plurality of fasteners extending through the fixing holes 126 of the functional module 10 to engage the threaded hole 724 of the second guiding block 70. One of the wedges 622 of the driving fork 62 is received in the receiving space 244 of the first lock member 20 to slidably engage the roller 26. The third driving rod 346 extends through the passage 762 of the second guiding block 70. Two end of the second driving rod 344 are respectively attached to the first driving rod 342 and the second driving rode 346. The other one of the wedges 622 of the driving fork 62 is received in the receiving space 3462 of the third driving rode 346 of the second lock member 30 to slidably engage the roller 36. At the same time, the bar 64 of the driving fork 60 extends through the passage 742 of the post 74 and the through hole 124 of the front wall 12; the coiled spring 104 is sleeved on the bar 64 and the threaded rod 84 of the button member 80 engages in the threaded hole of the bar 64. The coiled spring 104 is sandwiched between the operating portion 82 of the button member 80 and an outside of the front wall 12 of the functional module 10.

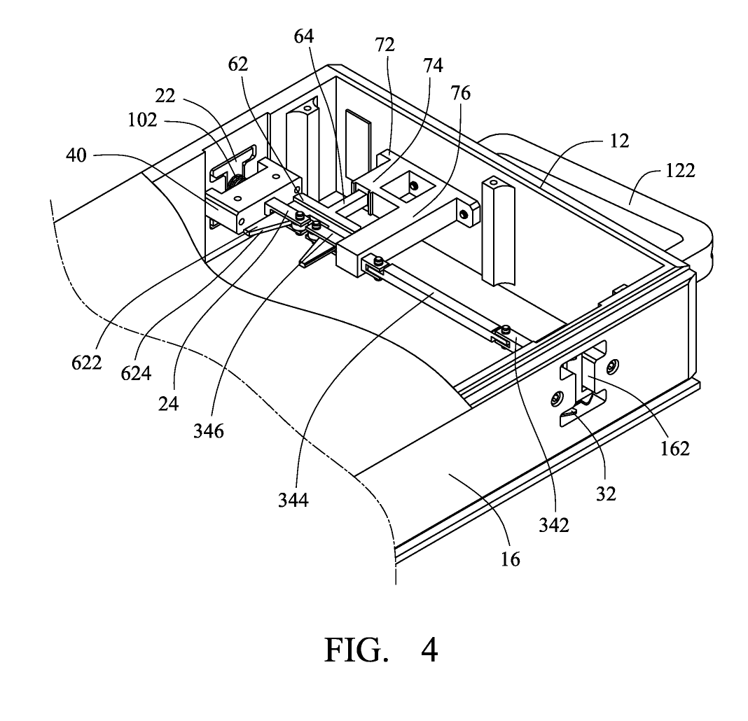

Referring also to FIGS. 3 and 4, in assembly of the functional module 10 to the chassis 200, the functional module 10 is pushed into the chassis 200 by operation of the handle 122, with the button member 80 pushed inward. The coil spring 104 is depressed and the driving fork 60 moved inward. The angled edges 624 of the driving fork 60 slidably engage the rollers 26, 36, respectively, to drive the first locking member 20 and the second driving member 30 to move toward each other. The coil springs 101 and 102 are depressed. The claws 22 of the first locking member 20 and the claws 32 of the second locking member 30 withdraw into the functional module 10 until the functional module 10 is received at a predetermined position of the chassis 200, at which time button member 80 is released. Then, the coil spring 104 recoils and the driving fork 60 returns to its original position. The coil springs 101, 102 recoil and the first and second locking members 20, 30 move opposite to each other to their original positions, respectively. The claws 22 of the first locking member 20 and the claws 32 of the second locking member 30 align with and extend into the openings 142, 162 of the functional module 10 and the fastening holes 204 of the chassis 200. Thus, the functional module 10 is retained in the chassis 200.

When the functional module 10 is to be detached from the chassis 200, the button member 80 is pushed inward to release the claws 22, 32 of the first and second locking members 20, 30 from the fastening holes 204 of the chassis 200. Correspondingly, the functional module 10 is easily withdrawn from the chassis 200.

In this embodiment, the rollers 26, 36 slidably engage the angled edges 624 of the driving fork 60 to effectively reduce friction therebetween. The rollers 26, 36 can be omitted, with the angled edges 624 of the driving fork 60 directly engaging the shafts 27, 37 of the first and second locking members 20, 30. The rollers 26, 36 and the angled edges 624 of the driving fork 60 can alternatively be replaced by other slidable mechanisms while remaining well within the scope of the disclosure.

It is to be understood, however, that even though numerous characteristics and advantages of the disclosure have been set forth in the foregoing description, together with details of the structure and function of the invention, the disclosure is illustrative only, and changes may be made in detail, especially in matters of shape, size, and arrangement of parts within the principles of the invention to the full extent indicated by the board general meaning of the terms in which the appended claims are expressed.

What is claimed is:

1. A fixing apparatus for a functional module, comprising:
a chassis comprising a sideboard defining a plurality of fastening holes;
a functional module comprising a front wall and a first sidewall;
a first locking member slidably attached to the first sidewall and comprising a plurality of claws corresponding to, and capable of engaging with, some of the plurality of fastening holes; and
a driving fork slidably attached to the front wall of the functional module and comprising at least one wedge slidably engaging the first locking member;
wherein the driving fork is able to slide relative to the front wall of the functional module to withdraw the plurality of claws of the first locking member from the corresponding fastening holes of the chassis or to extend the plurality of claws of the first locking member into the corresponding fastening holes of the chassis.

2. The fixing module as claimed in claim 1 further comprising a second locking member, wherein the chassis further comprises a second sideboard with a plurality of fastening holes, the functional module comprises a second sidewall to which the second locking member is slidably attached, the second locking member comprising a plurality of claws corresponding to, and capable of engaging with, the fastening holes of the second sideboard of the chassis, and the driving fork comprises a pair of symmetrical wedges slideably engaging the first and second locking members.

3. The fixing apparatus as claimed in claim 2 further comprising a pair of first guiding blocks attached to inner sides of the first and second sidewalls of the functional module, wherein each of the first guiding blocks comprises a passage defined therein, each of the first and second sidewalls comprises an opening therein, each of the first and second locking members comprises a flat panel and a driving arm extending therefrom, the driving arm extends through the corresponding opening of the functional module and the passage of the guiding blocks and engages the driving fork, and the claws extend from the flat panel facing away from the driving arm.

4. The fixing apparatus as claimed in claim 3, wherein two springs fixed around the driving arms of the first and second locking members are disposed between the flat panels of the first, and second locking members and the guiding blocks respectively.

5. The fixing apparatus as claimed in claim 3 further comprising a second guiding block attached to an inner side of the front wall of the functional module, wherein the second guiding block comprises a first post extending therefrom, the front wall of the functional module comprises a through hole defined therein, the first post comprises a passage defined therein, the driving fork comprises a bar extending through the passage of the first post and the through hole of the front wall, and the wedges are formed at one end of the bar.

6. The fixing apparatus as claimed in claim 5 further comprising a button member, attached to the other end of the bar, and a spring fixed around the bar is sandwiched between the button member and the front wall of the functional module.

7. The fixing apparatus as claimed in claim 5, wherein the second guiding block comprises a second post extending therefrom beside the first post, and a passage is defined in the post, through which the driving arm of the second locking member extends.

8. The fixing apparatus as claimed in claim 7, wherein the driving arm of the second locking member comprises a first driving rod, a second driving rod, and a third driving rod, and the second driving rod is capable of connecting between the first and third rods.

9. The fixing apparatus as claimed in claim 3, wherein each of the driving arms of the first and second locking members comprises a U-shaped receiving space defined in a distal end thereof for receiving a roller with pivot holes, a pair of pivot holes is defined in the distal end beside the receiving space, a shaft extends through the pivot holes of the driving arm and roller, and one of the wedges of the driving fork is received in the receiving space to slidably engage the roller.

10. A fixing apparatus comprising:
a chassis comprising a pair of sideboards each defining a plurality of fastening holes therein;
a functional module comprising a front wall, a first sidewall, and a second sidewall;
a driving fork slidably attached to the front wall of the functional module and comprising a pair of symmetrical wedges; and
a first locking member slidably attached to the first sidewall and a second locking member slidably attached to the second sidewall, the first and second locking members each comprising a plurality of claws corresponding to, and capable of engaging with, some of the plurality of fastening holes;
wherein the wedges are capable of slidably engaging the first and second locking members, respectively; the driving fork is able to slide relative to the front wall of the functional module between a first position in which the first and second locking members are moved toward each other to withdraw the claws from the fastening holes of the chassis, and a second position in which the first and second locking members are moved away from each other to extend the claws into the fastening holes of the chassis.
